(19) United States
(12) Patent Application Publication
(10) Pub. No.: US 2014/0175526 A1
(43) Pub. Date: Jun. 26, 2014

(54) SEMICONDUCTOR DEVICE FOR CURRENT CONTROL AND METHOD THEREOF

(71) Applicant: MACRONIX INTERNATIONAL CO., LTD., Hsin-chu (TW)

(72) Inventors: Kuo Hung Hsieh, Hsinchu County (TW); Meng Shien Hsieh, Changhua County (TW); Yin Fu Huang, Tainan City (TW); Miao Chun Chung, Miaoli County (TW)

(73) Assignee: MACRONIX INTERNATIONAL CO., LTD., Hsin-chu (TW)

(21) Appl. No.: 13/721,921

(22) Filed: Dec. 20, 2012

(51) Int. Cl. H01L 29/78; H01L 21/28

(52) U.S. Cl. CPC H01L 29/78; H01L 21/28008
USPC 257/288; 438/586

(57) ABSTRACT

A semiconductor device where at least one of a portion of the first metal layer that extends from the source contact, a portion of the second metal layer that extends from the source contact, a portion of the first metal layer that extends from the drain contact, and a portion of the second metal layer that extends from the drain contact is configured to lie above a portion of or even all of the gate. Methods of fabricating and using such a semiconductor device are also provided.

### TECHNOLOGICAL FIELD

The present invention generally relates to a semiconductor device. In particular, the present invention relates to a metal oxide semiconductor device and a method of fabricating a metal oxide semiconductor having variable current capability.

### BACKGROUND

FIG. 1A illustrates a cross-sectional view of a conventional metal oxide semiconductor (MOS) transistor. The MOS transistor 1 of this exemplary representation is disposed upon a substrate (not shown). Generally, a MOS comprises a source region 10, a drain region 20, a gate region 30, and a channel region 40. The source region 10 having a source contact 70 that extends from the metal-1 (M1) layer 60, and the drain region 20 having a drain contact 80 that extends from the metal-1 (M1) layer 62. The gate region 30 is defined by a gate 90, for example, a polysilicon gate, disposed on a field oxide layer 100, which is a gate insulating layer. A source side n+ well 110 and a drain side n+ well 120 are implanted into the substrate beneath the source contact 70 and the drain contact 80, simultaneously. The exemplary MOS transistor 1 of FIG. 1 shows a p-well 130 implant that may be used to regulate the transistor threshold voltage and to avoid punch-through voltage breakdown and an n-well 140 channel.

The substrate may be a p-type substrate or p-type backgate for an n-channel MOS (nMOS) transistor or an n-type substrate or n-type backgate for a p-channel MOS (pMOS) transistor. The active carriers in a pMOS are holes that migrate in the channel region 40 between the source contact 70 and drain contact 80, while the active carriers in an nMOS are electrons that migrate in the channel region 40 between the source contact 70 and drain contact 80.

FIG. 1B illustrates a cross-sectional view essentially of the MOS transistor of FIG. 1A but additionally showing a metal-2 (M2) layer 50 and 52.

The MOS transistor has three modes of operation depending upon the terminal voltages. FIG. 2 is a diagram showing MOS transistor terminal voltages V_{g} (gate terminal voltage), Vₛ (source terminal voltage), and V_{d} (drain terminal voltage). For example, the nMOS operates in a cutoff mode when a bias voltage V_{gs} between the gate and the source is less than the threshold voltage Vₜₕ of the MOS transistor. Essentially, in the cutoff mode, no channel develops and the current I_{ds} in the channel region 40 is zero.

The nMOS operates in a linear mode when the bias voltage V_{gs} exceeds the threshold voltage Vₜₕ as long as a channel voltage V_{ds} does not exceed a saturation voltage V_{ds,sat}. Typically, the saturation voltage is defined as the bias voltage V_{gs} less the threshold voltage Vₜₕ. The current I_{ds} increases with the channel voltage V_{ds} when the nMOS is in the linear mode. Finally, the channel pinches off and the current saturates when the channel voltage V_{ds} exceeds the saturation voltage V_{ds,sat}. I_{ds} is independent of V_{ds} when the nMOS transistor is in this saturation mode.

A disadvantage of the MOS transistor is the inability to necessarily control the value of the current I_{ds} without necessarily redesigning the structure of the MOS device as shown, for example, in FIGS. 1A or 1B. For example, without intending to be limiting, the current of a MOS transistor may depend upon the type of dopant and the extent of doping in any of the regions of the semiconductor, the dielectric thickness and the dielectric material, and the gate material. There remains a need in the art to more easily adjust the current realized in a given MOS transistor design without substantially changing the design of the MOS device.

### BRIEF SUMMARY OF EXEMPLARY EMBODIMENTS

Embodiments of the present invention are therefore provided that may provide for a semiconductor having variable current capability.

An aspect of the invention provides a semiconductor device comprising a source region and a diametrically opposed drain region, the source region having a source contact and the drain region having a drain contact; a gate region disposed between the source region and the drain region, the gate region having a gate; and one or more metal layers, wherein any of the one or more metal layers lies above at least a portion of the gate. In an embodiment of the invention, another portion of any of the one or more metal layers lies above at least another portion of the gate. In certain embodiments of the invention, the first portion and the second portion may at least include in part a same portion of the gate, while in other embodiments of the invention, the first portion and the second portion do not include a same portion of the gate.

According to an embodiment of the invention, wherein a coverage of the gate by the portion is any one of between about 0% and about 25%, at least about 25%, at least about 50%, at least about 75%, and about 100% or more. In certain embodiments of the invention, another coverage of the gate by the another portion is any one of between about 0% and about 25%, at least about 25%, at least about 50%, at least about 75%, and about 100% or more.

An embodiment of the invention is directed to a semiconductor device comprising a source region and a diametrically opposed drain region, the source region having a source contact and the drain region having a drain contact; a gate region disposed between the source region and the drain region, the gate region having a gate; and at least one metal layer. In certain embodiments of the invention, a portion of any one or more of the at least one metal layer extends from one or both of the source contact and the drain contact lies above at least a portion of the gate. For example, a coverage of the gate by any one of the portions may be between about 0% and about 25% according to an embodiment of the invention, at least about 25% according to another embodiment of the invention, at least about 50% according to yet another embodiment of the invention, at least about 75% according to even yet another embodiment of the invention, or about 100% or more in yet another embodiment of the invention. In an embodiment of the invention, another coverage of the gate by another one of the portions may be between about 0% and about 25% according to an embodiment of the invention, at least about 25% according to another embodiment of the invention, at least about 50% according to yet another embodiment of the invention, at least about 75% according to even yet another embodiment of the invention, or about 100% (or more) in yet another embodiment of the invention.

An aspect of the invention provides a system for varying a current in a semiconductor device comprising a semiconductor having a gate, a source contact, and a drain contact; and at least one metal layer, any one or more of the at least one metal layer having a portion that extends from one or both of the source contact and the drain contact to lie above at least a portion of the gate. For example, a coverage of the gate by the portion is any one of between about 0% and about 25%, at least about 25%, at least about 50%, at least about 75%, and about 100% or more.

According to a more specific embodiment of the invention, a coverage of the gate by the portion of a first metal layer that extends from the source contact is any one of between about 0% and about 25%, at least about 25%, at least about 50%, at least about 75%, and about 100% or more. In another embodiment of the invention, a coverage of the gate by the portion of a second metal layer that extends from the source contact is any one of between about 5% and about 25%, at least about 25%, at least about 50%, at least about 75%, and about 100% or more. In yet another embodiment of the invention, another coverage of the gate by the portion of the first metal layer that extends from the drain contact is any one of between about 0% and about 25%, at least about 25%, at least about 50%, at least about 75%, and about 100% or more. In even yet another embodiment of the invention, another coverage of the gate by the portion of the second metal layer that extends from the drain contact is any one of between about 0% and about 25%, at least about 25%, at least about 50%, at least about 75%, and about 100% or more.

An aspect of the invention provides a method of fabricating a semiconductor device comprising providing a semiconductor comprising a gate region having a gate, a source region having a source contact, and a drain region having a drain contact; forming an interlayer dielectric layer on the semiconductor; etching the interlayer dielectric layer to define the source contact and the drain contact; depositing a metal layer across the interlayer dielectric layer additionally filling the source contact and the drain contact; and removing one or more portions of the metal layer to define a first metal layer. In an embodiment of the invention, a portion of the first metal layer extends from at least one of the source contact and the drain contact and lies above at least a portion of the gate. For example, a coverage of the gate by the portion of the first metal layer is any one of between about 0% and about 25%, at least about 25%, at least about 50%, at least about 75%, and about 100% or more.

The method of fabricating a semiconductor may additionally comprise the steps of forming another interlayer dielectric layer on the semiconductor; etching the another interlayer dielectric layer to define one or more contacts; depositing another metal layer across the another interlayer dielectric layer; and removing one or more portions of the another metal layer to define a second metal layer. Further pursuant to this embodiment of the invention, a portion of the second metal layer may extend from at least one of the source contact and the drain contact and lies above at least a portion of the gate. For example, another coverage of the gate by the portion of the second metal layer is any one of between about 0% and about 25%, at least about 25%, at least about 50%, at least about 75%, and about 100% or more.

An aspect of the invention provides a method of operating a semiconductor comprising the steps of providing a semiconductor comprising a gate region having a gate, a source region having a source contact, a drain region having a drain contact, and a channel region, the semiconductor is configured to have a threshold voltage Vₜₕ, a saturation voltage V_{ds,sat}, which is typically a bias voltage V_{gs} between the gate and the source contact less the threshold voltage Vₜₕ, and a current I_{ds}; applying a voltage V_{g} to the gate; cutting off the operation of the semiconductor when the bias voltage V_{gs} is less than the threshold voltage Vₜₕ; increasing the current I_{ds} substantially linearly relative to a voltage across the channel region Vₐₛ defined substantially as the region between the source contact and the drain contact, when the bias voltage V_{gs} is greater than the threshold voltage Vₜₕ and a voltage across the channel region Vₐₛ between the source contact and the drain contact is less than the saturation voltage V_{ds,sat;} and pinching off the channel region causing the current I_{ds} to become substantially independent of the voltage across the channel region V_{ds} when the voltage across the channel region V_{ds} is greater than or equal to the saturation voltage V_{ds,sat}. Further pursuant to this embodiment, a value of the current I_{ds} may be at least determined in part by at least one of a first portion of a first metal layer that extends from the source contact, a first portion of a second metal layer that extends from the source contact, a second portion of the first metal layer that extends from the drain contact, and a second portion of the second metal layer that extends from the drain contact. According to an embodiment of the invention, a coverage of the gate by the first portion of the first metal layer that extends from the source contact is any one of between about 0% and about 25%, at least about 25%, at least about 50%, at least about 75%, and about 100% or more.

In another embodiment of the invention, a coverage of the gate by the first portion of the second metal layer that extends from the source contact is any one of between about 0% and about 25%, at least about 25%, at least about 50%, at least about 75%, and about 100% or more. In yet another embodiment of the invention, another coverage of the gate by the first portion of the first metal layer that extends from the drain contact is any one of between about 0% and about 25%, at least about 25%, at least about 50%, at least about 75%, and about 100% or more. In even yet another embodiment of the invention, another coverage of the gate by the first portion of the second metal layer that extends from the drain contact is any one of between about 0% and about 25%, at least about 25%, at least about 50%, at least about 75%, and about 100% or more.

The method of operating a semiconductor may additionally comprise at least one metal layer above the first metal layer and the second metal layer with a portion of said at least one metal layer that extends from any one or both of the source contact and the drain contact and lies above at least a portion of the gate.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1A illustrates a cross-sectional view of a conventional MOS transistor;

FIG. 1B illustrates a cross-sectional view of another conventional MOS transistor;

FIG. 2 is a diagram showing MOS transistor terminal voltages;

FIG. 3A illustrates a cross-sectional view of a MOS according to an embodiment of the invention;

FIG. 3B illustrates a cross-sectional view of a MOS according to an embodiment of the invention;

FIG. 4 is a graphical representation of the current versus the extent of coverage a first and a second metal layer that extend from the source side according to certain embodiments of the invention;

FIG. 5A illustrates a cross-sectional view of a MOS according to another embodiment of the invention;

FIG. 5B illustrates a cross-sectional view of a MOS according to another embodiment of the invention;

FIG. 6 is a graphical representation of the current versus the extent of coverage of a first and second metal layer that extend from the drain side according to certain embodiments of the invention;

FIG. 7A illustrates a cross-sectional view of a first metal layer configured to lie above a gate structure according to an embodiment of the invention;

FIG. 7B illustrates a cross-sectional view of a first metal layer configured to lie above a gate structure according to another embodiment of the invention;

FIG. 8A illustrates a cross-sectional view of a second metal layer configured to lie above a gate structure according to an embodiment of the invention;

FIG. 8B illustrates a cross-sectional view of a second metal layer configured to lie above a gate structure according to another embodiment of the invention;

FIG. 9A illustrates a cross-sectional view of a first metal layer and a second metal layer configured to lie above a gate structure according to an embodiment of the invention;

FIG. 9B illustrates a cross-sectional view of a first metal layer and a second metal layer configured to lie above a gate structure according to another embodiment of the invention;

FIG. 10 is a flowchart of a process for fabricating a semiconductor according to an embodiment of the invention; and

FIG. 11 is a flowchart showing a method of operating a semiconductor device according to an embodiment of the invention.

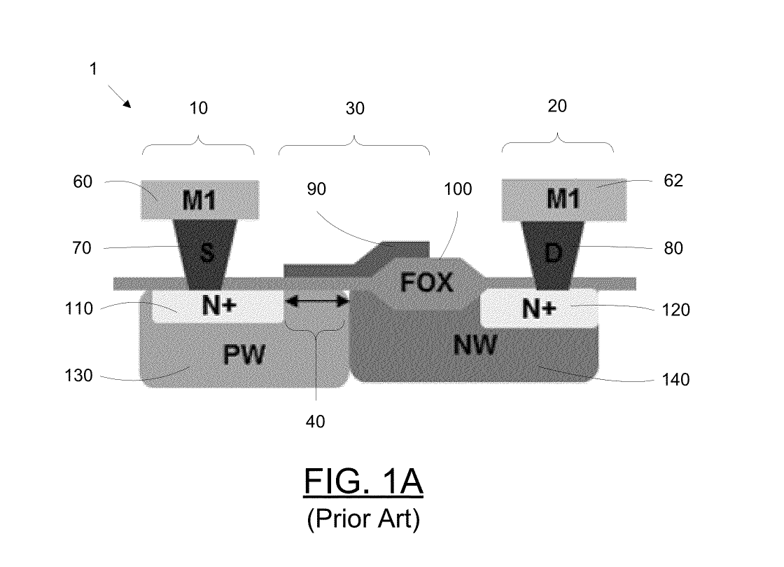

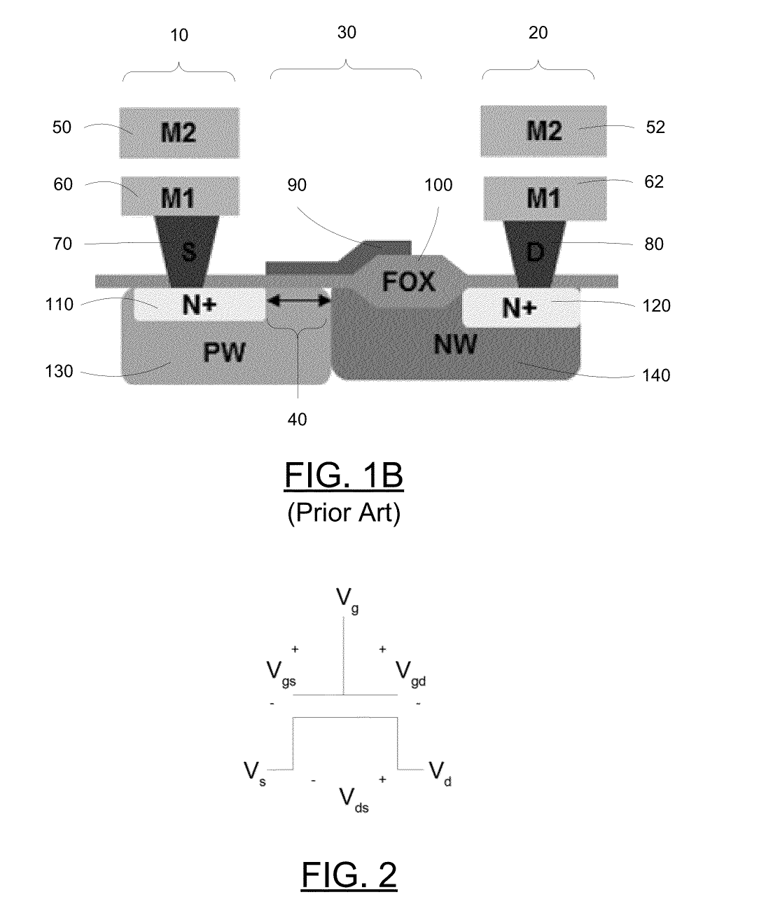

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a MOS transistor” includes a plurality of such MOS transistors.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, a “substrate” may include any underlying material or materials upon which a device, a circuit, an epitaxial layer, or a semiconductor may be formed. Generally, a substrate may be used to define the layer or layers that underlie a semiconductor device or even forms the base layer of a semiconductor device. Without intending to be limiting, materials of a substrate may include one or any combination of a silicon, a doped silicon, a gallium arsenide (GaAs), a gallium arsenide phosphide (GaAsP), an indium phosphide (InP), a germanium (Ge), or a silicon germanium (SiGe). The substrate may additional comprise a dielectric layer. For example, the dielectric layer may be any one of a silicon oxide (SiO₂), a silicon nitride (Si₃N₄), a silicon oxynitride (SiOₓN_{y}), and any combination thereof.

The inventors have conceived of and have developed a MOS device and methods for fabricating such a MOS device as well as methods of operating such a MOS device whereby the MOS device is capable of having a variable current capacity commensurate with certain design and/or operational features of the device.

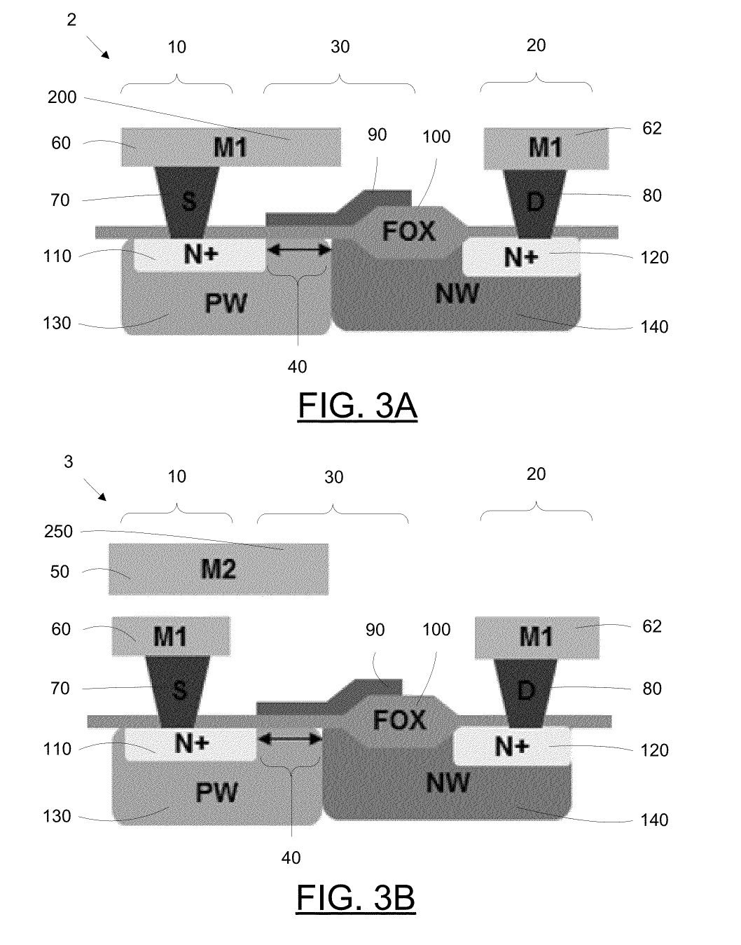

FIG. 3A illustrates a cross-section of a semiconductor according to an embodiment of the invention. As shown in FIG. 3A, a portion of the M1 layer 200 extends from the source contact 70 of semiconductor 2 is configured to overlie or to lie above a portion of the gate 90. As used herein, “coverage” is the extent of the amount measured in percent that the portion of the M1 layer 200 overlies or lies above the gate 90 based upon the overall length of the gate 90. For example, the coverage is 0% when no portion of the M1 layer 200 overlies or lies above the gate 90. On the other hand, when the portion of the M1 layer 200 overlies or lies above ½ of the gate 90, then the coverage is 50%. Finally, by way of example, when the portion of the M1 layer 200 fully overlies or lies above or even extends beyond the gate 90, then the coverage is 100%. In certain embodiments of the invention, the coverage of the portion of the M1 layer 200 that extends from the source contact 70 is between about 0% and about 25%, between about 5% and about 25%, about 25%, at least about 25%, about 50%, at least about 50%, about 75%, at least about 75%, about 100%, or at least about 100%. In certain embodiments of the invention, the coverage of the portion of the M1 layer 200 that extends from the source contact 70 is about 100%. In certain embodiments of the invention, the coverage of the portion of the M1 layer 200 that extends from the source contact 70 is established by the current profiles desired for the semiconductor.

FIG. 3B illustrates a cross-section of a semiconductor according to an embodiment of the invention. As shown in FIG. 3B, a portion of the M2 layer 250 that extends from the source contact 70 of semiconductor 3 is configured to overlie or lie above a portion of the gate 90. In certain embodiments of the invention, the coverage of the portion of the M2 layer 250 that extends from the source contact 70 is between about 0% and about 25%, between about 5% and about 25%, about 25%, at least about 25%, about 50%, at least about 50%, about 75%, at least about 75%, about 100%, or at least about 100%. In certain embodiments of the invention, the coverage of the portion of the M2 layer 250 that extends from the source contact 70 is about 100%. In certain embodiments of the invention, the coverage of the portion of the M2 layer 250 that extends from the source contact 70 is established by the current profiles desired for the semiconductor.

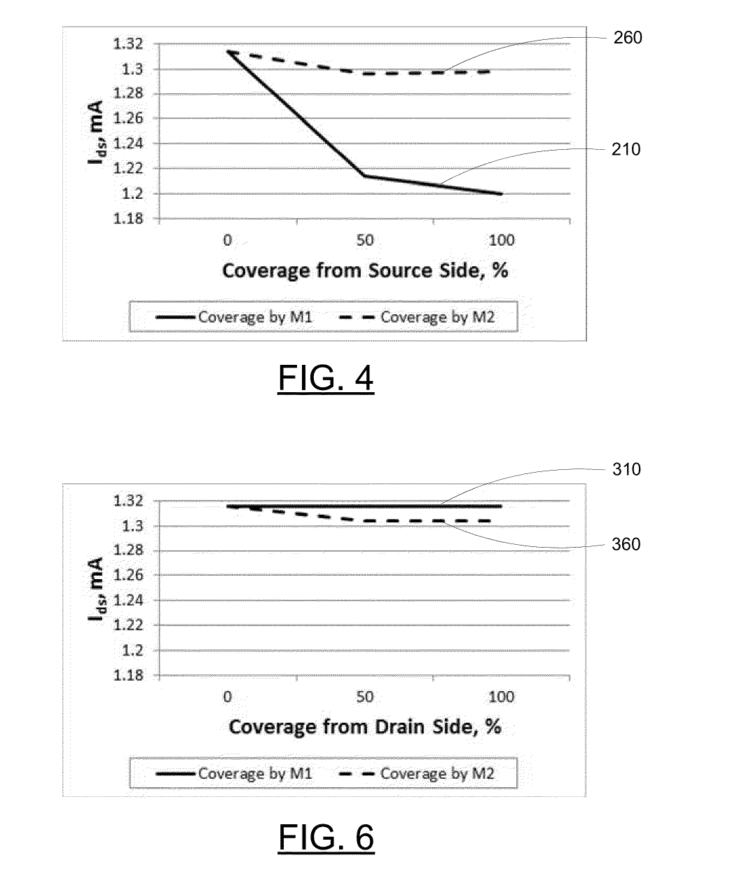

FIG. 4 is a graphical representation of the current versus the extent of coverage of a first and a second metal layer that extend from the source side according to certain embodiments of the invention. The effect of increasing the amount of coverage of the portion of the M1 layer 200 that extends from the source contact 70 is shown in the curve labeled 210 in FIG. 4. Curve 210 shows that increasing amount of coverage of the portion of the M1 layer 200 that extends from the source contact 70 causes a decrease in the current.

The effect of increasing the amount of coverage of the portion of the M2 layer 250 that extends from the source contact 70 is shown in the curve labeled 260 in FIG. 4. Curve 260 shows that increasing amounts of coverage of the portion of the M2 layer 250 that extends from the source contact 70 causes a decrease in the current, although the extent of decrease is not as great as that realized by increasing the amount of coverage of the portion of the M1 layer 200 that extends from the source contact 70 as shown in curve 210.

In certain embodiments of the invention, both the portion of the M1 layer 200 that extends from the source contact 70 and the portion of the M2 layer 250 that extends from the source contact 70 may each be configured to overlie or lie above the gate 90. According to certain embodiments of the invention, the coverage of the M1 layer 200 that extends from the source contact 70 and the coverage of the M2 layer 250 that extends from the source contact 70, respectively, are between about 0% and about 25%, between about 0% and about 25%; between about 0% and about 25%, between about 5% and about 25%; between about 0% and about 25%, at least about 25%; between about 0% and about 25%, at least about 50%; between about 0% and about 25%, at least about 75%; between about 0% and about 25%, about 100% or more; between about 5% and about 25%, between about 0% and about 25%; between about 5% and about 25%, between about 5% and about 25%; between about 5% and about 25%, at least about 25%; between about 5% and about 25%, at least about 50%; between about 5% and about 25%, at least about 75%; between about 5% and about 25%, about 100% or more; at least about 25%, between about 0% and about 25%; at least about 25%, between about 5% and about 25%; at least about 25%, at least about 25%; at least about 25%, at least about 50%; at least about 25%, at least about 75%; at least about 25%, about 100% or more; at least about 50%, between about 0% and about 25%; at least about 50%, between about 5% and about 25%; at least about 50%, at least about 25%; at least about 50%, at least about 50%; at least about 50%, at least about 75%; at least about 50%, about 100% or more; at least about 75%, between about 0% and about 25%; at least about 75%, between about 5% and about 25%; at least about 75%, at least about 25%; at least about 75%, at least about 50%; at least about 75%, at least about 75%; at least about 75%, about 100% or more; about 100% or more, between about 0% and about 25%; about 100% or more, between about 5% and about 25%; about 100% or more, at least about 25%; about 100% or more, at least about 50%; about 100% or more, at least about 75%; and about 100% or more, about 100% or more. In certain other embodiments of the invention, both the coverage of the portion of the M1 layer 200 that extends from the source contact 70 and the coverage of the portion of the M2 layer 250 that extends from the source contact 70 may be established by the current profiles desired for the semiconductor.

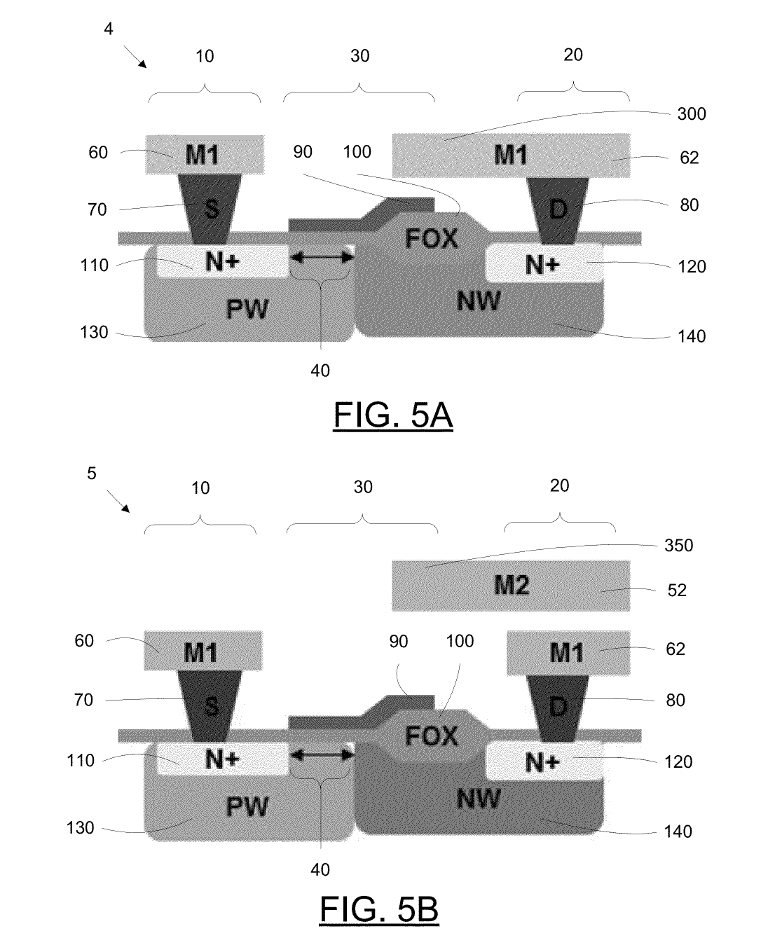

FIG. 5A illustrates a cross-section of a semiconductor according to another embodiment of the invention. As shown in FIG. 5A, a portion of the M1 layer 300 that extends from the drain contact 80 of semiconductor 4 is configured to overlie or lie above a portion of the gate 90. In certain embodiments of the invention, the coverage of the portion of the M1 layer 300 that extends from the drain contact 80 is between about 0% and about 25%, between about 5% and about 25%, about 25%, at least about 25%, about 50%, at least about 50%, about 75%, at least about 75%, about 100%, or at least about 100%. In certain embodiments of the invention, the coverage of the portion of the M1 layer 300 that extends from the drain contact 80 is about 100%. In certain embodiments of the invention, the coverage of the portion of the M1 layer 300 that extends from the drain contact 80 is established by the current profiles desired for the semiconductor.

FIG. 5B illustrates a cross-section of a semiconductor according to another embodiment of the invention. As shown in FIG. 5B, a portion of the M2 layer 350 that extends from the drain contact 80 of semiconductor 5 is configured to overlie or lie above a portion of the gate 90. In certain embodiments of the invention, the coverage of the portion of the M2 layer 350 that extends from the drain contact 80 is between about 0% and about 25%, between about 5% and about 25%, about 25%, at least about 25%, about 50%, at least about 50%, about 75%, at least about 75%, about 100%, or at least about 100%. In certain embodiments of the invention, the coverage of the portion of the M2 layer 350 that extends from the drain contact 80 is about 100%. In certain embodiments of the invention, the coverage of the portion of the M2 layer 350 that extends from the drain contact 80 is established by the current profiles desired for the semiconductor.

FIG. 6 is a graphical representation of the current versus the extent of coverage a first and a second metal layer extend from the drain side according to certain embodiments of the invention. The effect of increasing the amount of coverage of the portion of the M1 layer 300 that extends from the drain contact 80 is shown in the curve labeled 310 in FIG. 6. Curve 310 shows that increasing amount of coverage of the portion of the M1 layer 300 that extends from the drain contact 80 has little to substantially no effect on the current.

The effect of increasing the amount of coverage of the portion of the M2 layer 350 that extends from the drain contact 80 is shown in the curve labeled 360 in FIG. 5. Curve 360 shows that increasing amount of coverage of the portion of the M2 layer 350 that extends from the drain contact 80 causes a slight decrease in the current. The extent of reduction in current resulting from increasing the amount of coverage of the portion of the M1 layer 200 that extends from the source contact 70 and/or increasing the amount of coverage of the portion of the M2 layer 250 that extends from the source contact 70 has a greater effect on the current than increasing the amount of coverage of the portion of the M1 layer 300 that extends from the drain contact 80 and/or increasing the amount of coverage of the portion of the M2 layer 350 that extends from the drain contact 80.

In certain embodiments of the invention, both the portion of the M1 layer 300 that extends from the drain contact 80 and the portion of the M2 layer 350 that extends from the drain contact 80 may each be configured to overlie or lie above the gate 90. According to certain embodiments of the invention, the coverage of the M1 layer 300 that extends from the drain contact 80 and the coverage of the M2 layer 350 that extends from the drain contact 80, respectively, are between about 0% and about 25%, between about 0% and about 25%; between about 0% and about 25%, between about 5% and about 25%; between about 0% and about 25%, at least about 25%; between about 0% and about 25%, at least about 50%; between about 0% and about 25%, at least about 75%; between about 0% and about 25%, about 100% or more; between about 5% and about 25%, between about 0% and about 25%; between about 5% and about 25%, between about 5% and about 25%; between about 5% and about 25%, at least about 25%; between about 5% and about 25%, at least about 50%; between about 5% and about 25%, at least about 75%; between about 5% and about 25%, about 100% or more; at least about 25%, between about 0% and about 25%; at least about 25%, between about 5% and about 25%; at least about 25%, at least about 25%; at least about 25%, at least about 50%; at least about 25%, at least about 75%; at least about 25%, about 100% or more; at least about 50%, between about 0% and about 25%; at least about 50%, between about 5% and about 25%; at least about 50%, at least about 25%; at least about 50%, at least about 50%; at least about 50%, at least about 75%; at least about 50%, about 100% or more; at least about 75%, between about 0% and about 25%; at least about 75%, between about 5% and about 25%; at least about 75%, at least about 25%; at least about 75%, at least about 50%; at least about 75%, at least about 75%; at least about 75%, about 100% or more; about 100% or more, between about 0% and about 25%; about 100% or more, between about 5% and about 25%; about 100% or more, at least about 25%; about 100% or more, at least about 50%; about 100% or more, at least about 75%; and about 100% or more, about 100% or more. In certain other embodiments of the invention, both the coverage of the portion of the M1 layer 300 that extends from the drain contact 80 and the coverage of the portion of the M2 layer 350 that extends from the drain contact 80 may be established by the current profiles desired for the semiconductor. In certain other embodiments of the invention, another coverage of the portion of the M1 layer 300 that extends from the drain contact 80 and/or another coverage of the portion of the M2 layer 350 that extends from the drain contact 80 may be used in combination with the portion of the M1 layer 200 that extends from the source contact 70 and/or the coverage of the portion of the M2 layer 250 that extends from the source contact 70 to establish by the current profiles desired for the semiconductor.

In certain other embodiments of the invention, the combination of some or all of the portion of the M1 layer 200 that extends from the source contact 70, the portion of the M2 layer 250 that extends from the source contact 70, the portion of the M1 layer 300 that extends from the drain contact 80, and the portion of the M2 layer 350 that extends from the drain contact 80 may each be adjusted to provide a desired current profile.

In other embodiments of the invention, a portion of any metal layer above the first and second metal layer extend beyond any one or both of the source contact and the drain contact to lie above at least a portion of the gate may be used to vary the current in the semiconductor device.

In certain embodiments of the invention, the extent of coverage of the gate 90 by any one of, any combination of, or even all of the portion of the M1 layer 200 that extends from the source contact 70, the portion of the M2 layer 250 that extends from the source contact 70, the portion of the M1 layer 300 that extends from the drain contact 80, and the portion of the M2 layer 350 that extends from the drain contact 80 may be used in combination with spacers formed by high density plasma (HDP) techniques in a self-aligned process to provide a semiconductor device.

In certain other embodiments of the invention, the extent of coverage of the gate 90 by any one of, any combination of, or even all of the portion of the M1 layer 200 that extends from the source contact 70, the portion of the M2 layer 250 that extends from the source contact 70, the portion of the M1 layer 300 that extends from the drain contact 80, and the portion of the M2 layer 350 that extends from the drain contact 80 may be used in combination with the amount of polysilicon used in the gate 90 to provide a desire impendence of the semiconductor device of the invention.

In certain embodiments of the invention, the extent of coverage of the gate 90 by any one of, any combination of, or even all of the portion of the M1 layer 200 that extends from the source contact 70, the portion of the M2 layer 250 that extends from the source contact 70, the portion of the M1 layer 300 that extends from the drain contact 80, and the portion of the M2 layer 350 that extends from the drain contact 80 may be used in combination with the polysilicon gate 90 to established a preferred resistance of the semiconductor device.

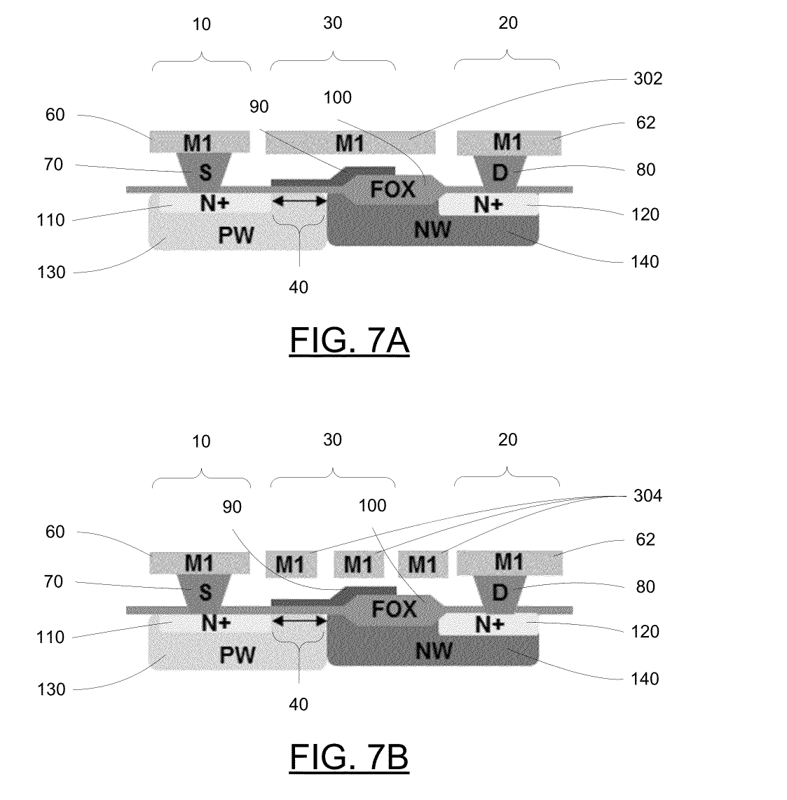

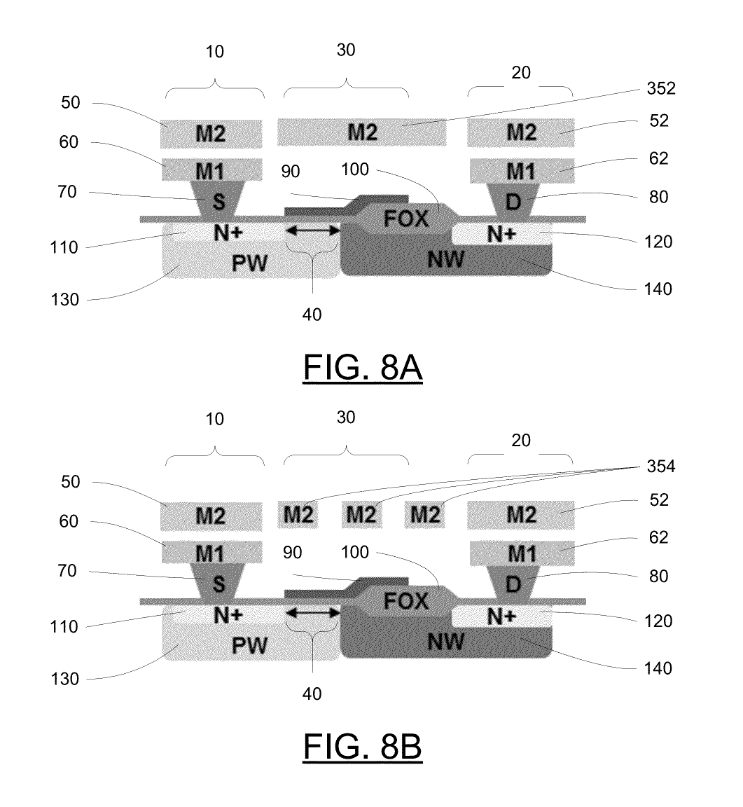

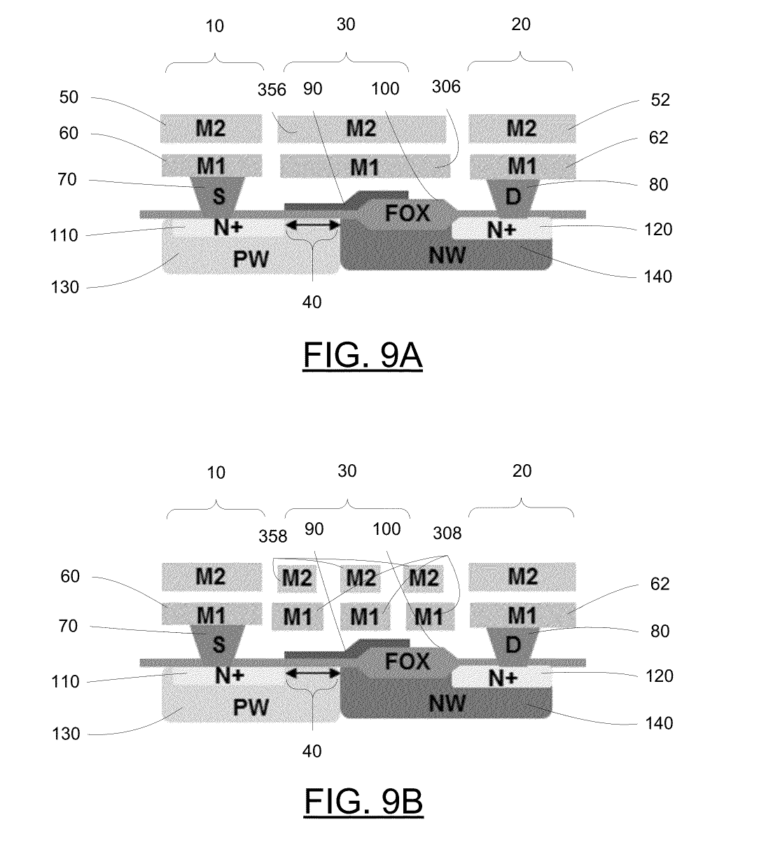

FIGS. 7A and 7B illustrate cross-sectional views of a first metal layer 302 and 304, respectively, configured to lie above a gate structure according to several other exemplary embodiments of the invention. FIGS. 8A and 8B illustrate cross-sectional views of a second metal layer 352 and 354, respectively, configured to lie above a gate structure according to several other exemplary embodiments of the invention. FIGS. 9A and 9B illustrate cross-sectional views of a first metal layer 306 and 308, respectively, and a second metal layer 356 and 358, respectively, both layers configured to lie above a gate structure according to several other exemplary embodiments of the invention. Generally, the embodiments represented by these figures do not directly extend from the source contact or the drain contact, but yet either or both of the metal layers are configured to lie above the gate.

An embodiment of the invention is directed to a system for varying the current in a semiconductor comprising a semiconductor having a gate, a source contact, and a drain contact; and a portion of at least one metal layer that extends from one or both of the source contact and the drain contact to lie above at least a portion of the gate. According to an embodiment of the invention, a coverage of the gate is between about 0% and about 25%, between about 5% and about 25%, about 25%, at least about 25%, about 50%, at least about 50%, about 75%, at least about 75%, about 100%, and about 100% or more of the length of the gate.

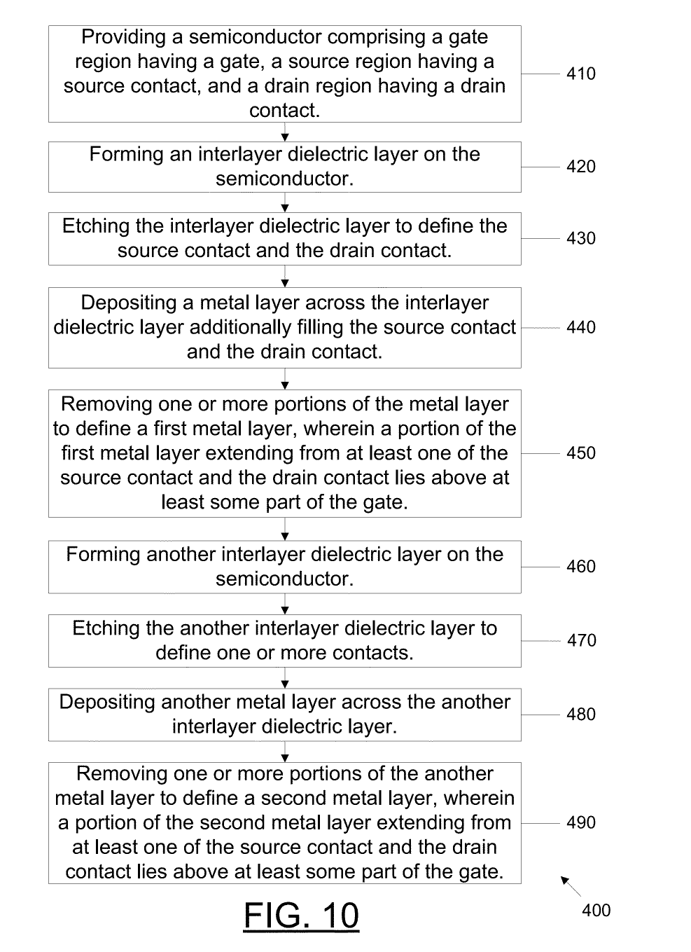

An aspect of the invention provides a method of fabricating a semiconductor. While the order of the steps of the method for fabricating a semiconductor may be variable, generally, the steps in a method of fabricating a semiconductor 400, as shown in the process flowchart of FIG. 10 include providing a semiconductor comprising a gate region having a gate, a source region having a source contact, and a drain region having a drain contact 410; forming an interlayer dielectric layer on the semiconductor 420; etching the interlayer dielectric layer to define the source contact and the drain contact 430; depositing a metal layer across the interlayer dielectric layer additionally filling the source contact and the drain contact 440; and removing one or more portions of the metal layer to define a first metal layer, wherein a portion of the first metal layer that extends from at least one of the source contact and the drain contact lies above at least some part of the gate 450.

The method of fabricating a semiconductor 400 may additionally comprise forming another interlayer dielectric layer on the semiconductor 460; etching the another interlayer dielectric layer to define one or more contacts 470; depositing another metal layer across the another dielectric layer 480; and removing one or more portions of the another metal layer to define a second metal layer, wherein a portion of the second metal layer that extends from at least one of the source contact and the drain contact lies above at least some part of the gate 490.

According to certain embodiments of the invention, the method of fabricating a semiconductor 400 may involve the formation of additional metal layers beyond the first and second metal layers shown in the exemplary embodiment represented by FIG. 10. Any one or more of these additional layers may extend from at least one of the source contact and the drain contact to lie above at least a portion of the gate. The extent of coverage of any of the metal layers is pursuant to the disclosure provided herein.

An aspect of the invention provides a semiconductor fabricated using the processes or methods for fabricating a semiconductor of the invention. In certain other embodiments of the invention, a semiconductor device may be fabricated using any of the methods as described herein.

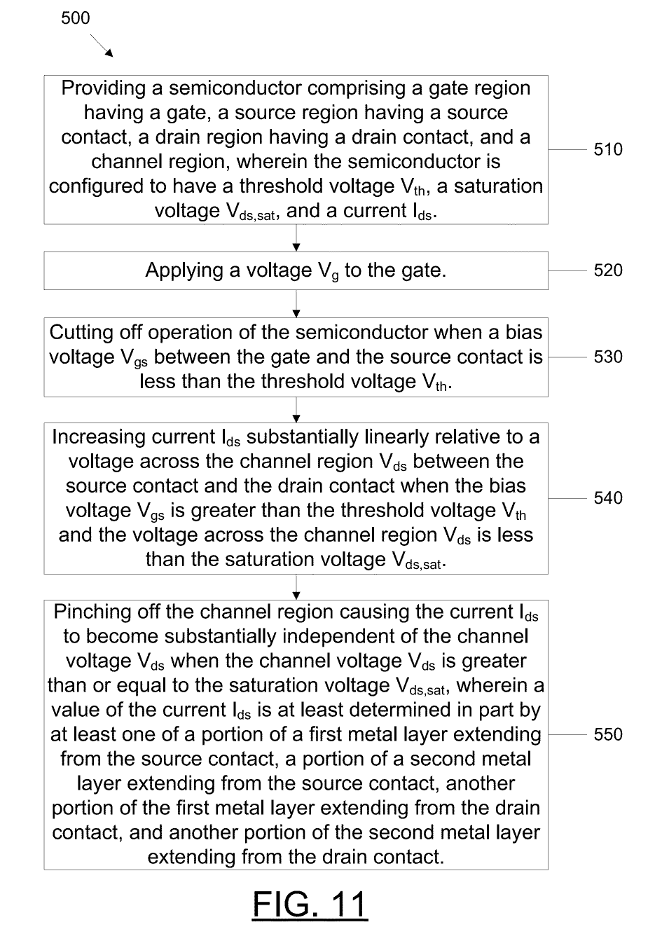

An aspect of the invention also provides a method of operating a semiconductor device. The method of operating a semiconductor device 500, as shown in the process flowchart of FIG. 11, includes the steps of providing a semiconductor comprising a gate region having a gate, a source region having a source contact, a drain region having a drain contact, and a channel region, wherein the semiconductor is configured to have a threshold voltage Vₜₕ, a saturation voltage V_{ds,sat,} and a current I_{ds} 510 and applying a voltage V_{g} to the gate 520. As further shown in FIG. 11, the method of operating a semiconductor device 500 may additionally comprise the operational steps of cutting off the operation of the semiconductor when a bias voltage V_{gs} between the gate and the source contact is less than the threshold voltage Vₜₕ 530; increasing the current I_{ds} substantially linearly relative to a voltage across the channel region V_{ds} between the source contact and the drain contact when the bias voltage V_{gs} is greater than the threshold voltage Vₜₕ and the voltage across the channel region Vₐₛ is less than the saturation voltage V_{ds,sat} 540; and pinching off the channel region causing the current I_{ds} to become substantially independent of the channel voltage Vₐₛ when the channel voltage V_{ds} is greater than or equal to the saturation voltage V_{ds,sat} 550. In certain embodiments of the invention, the saturation voltage may be defined as the bias voltage V_{gs} less the threshold voltage Vₜₕ.

Pursuant to the method of operating a semiconductor device 500, a value of the current I_{ds} is at least determined in part by at least one of a portion of a first metal layer that extends from the source contact, a portion of a second metal layer that extends from the source contact, another portion of the first metal layer that extends from the drain contact, and another portion of the second metal layer that extends from the drain contact.

Further pursuant to this embodiment of the invention, a portion of any one or more of metal layers above the first and second metal layers may extend from at least one of the source contact and the drain contact to lie above at least a portion of the gate at least determine in part the value of the current I_{ds}. The extent of the amount that any portion of any of the metal layers lie above the gate may be determined as further provided herein.

In addition to the applicability of the invention to nMOS and pMOS, the invention also has applicability to LDMOS, EDMOS, double diffused drain metal oxide semiconductors (DDDMOS), lightly doped drain metal oxide semiconductors (LDDMOS), and any other semiconductor that is affected one or more applied metal layers.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A semiconductor device comprising:
a source region and a diametrically opposed drain region, the source region having a source contact and the drain region having a drain contact;
a gate region disposed between the source region and the drain region, the gate region having a gate; and
one or more metal layers,
wherein a portion of any of the one or more metal layers lies above at least a portion of the gate.

2. The semiconductor device of claim 1, wherein another portion of any of the one or more metal layers lies above at least another portion of the gate.

3. The semiconductor device of claim 1, wherein a coverage of the gate by the portion is any one of between about 0% and about 25%, at least about 25%, at least about 50%, at least about 75%, and about 100% or more.

4. The semiconductor device of claim 1, wherein another coverage of the gate by the another portion is any one of between about 0% and about 25%, at least about 25%, at least about 50%, at least about 75%, and about 100% or more.

5. A semiconductor device comprising:
a source region and a diametrically opposed drain region, the source region having a source contact and the drain region having a drain contact;
a gate region disposed between the source region and the drain region, the gate region having a gate; and
at least one metal layer,
wherein a portion of any one or more of the at least one metal layer extends from one or both of the source contact and the drain contact and lies above at least a portion of the gate.

6. The semiconductor device of claim 5, a coverage of the gate by any one of the portion is any one of between about 0% and about 25%, at least about 25%, at least about 50%, at least about 75%, and about 100% or more.

7. The semiconductor device of claim 5, a coverage of the gate by any one of the portion of a first metal layer that extends from the source contact is any one of between about 0% and about 25%, at least about 25%, at least about 50%, at least about 75%, and about 100% or more.

8. The semiconductor device of claim 5, a coverage of the gate by any one of the portion of a second metal layer that extends from the source contact is any one of between about 0% and about 25%, at least about 25%, at least about 50%, at least about 75%, and about 100% or more.

9. The semiconductor device of claim 5, another coverage of the gate by any one of the portion of a first metal layer that extends from the drain contact is any one of about 0% and about 25%, at least about 25%, at least about 50%, at least about 75%, and about 100% or more.

10. The semiconductor device of claim 5, another coverage of the gate by any one of the portion of a second metal layer that extends from the drain contact is any one of between about 0% and about 25%, at least about 25%, at least about 50%, at least about 75%, and about 100% or more.

11-17. (canceled)

18. A method of fabricating a semiconductor device comprising:
providing a semiconductor comprising a gate region having a gate, a source region having a source contact, and a drain region having a drain contact;
forming an interlayer dielectric layer on the semiconductor;
etching the interlayer dielectric layer to define the source contact and the drain contact;
depositing a metal layer across the interlayer dielectric layer additionally filling the source contact and the drain contact; and
removing one or more portions of the metal layer to define a first metal layer,
wherein a portion of the first metal layer extends from at least one of the source contact and the drain contact and lies above at least a portion of the gate.

19. The method of claim 18, wherein a coverage of the gate by the portion of the first metal layer is any one of between about 0% and about 25%, at least about 25%, at least about 50%, at least about 75%, and about 100% or more.

20. The method of claim 18 additionally comprising:
forming another interlayer dielectric layer on the semiconductor;
etching the another interlayer dielectric layer to define one or more contacts;
depositing another metal layer across the another interlayer dielectric layer; and
removing one or more portions of the another metal layer to define a second metal layer,
wherein a portion of the second metal layer extends from at least one of the source contact and the drain contact and lies above at least a portion of the gate.

21. The method of claim 19, wherein another coverage of the gate by the portion of the second metal layer is any one of between about 0% and about 25%, at least about 25%, at least about 50%, at least about 75%, and about 100% or more.

22. (canceled)
